(19) United States
(12) Patent Application Publication
(10) Pub. No.: US 2023/0322818 A1
(43) Pub. Date: Oct. 12, 2023

(54) SILICON COMPOUND, REACTIVE MATERIAL, RESIN COMPOSITION, PHOTOSENSITIVE RESIN COMPOSITION, CURED FILM, METHOD OF MANUFACTURING CURED FILM, PATTERNED CURED FILM, AND METHOD OF MANUFACTURING PATTERNED CURED FILM

(71) Applicant: CENTRAL GLASS COMPANY, LIMITED, Ube-shi, Yamaguchi (JP)

(72) Inventors: Takashi MASUBUCHI, Kawagoe-shi, Saitama (JP); Yuri OIKAWA, Kawagoe-shi, Saitama (JP); Kazuhiro YAMANAKA, Kawagoe-shi, Saitama (JP)

(21) Appl. No.: 17/768,378

(22) PCT Filed: Oct. 21, 2020
(86) PCT No.: PCT/JP2020/039508

§ 371 Date: Jun. 29, 2023

(30) Foreign Application Priority Data
Oct. 28, 2019 (JP) 2019-195382

(51) Int. Cl. C07F 7/18; C08G 77/24; C08G 77/00; C08G 77/08; G03F 7/075; G03F 7/20

(52) U.S. Cl. CPC C07F 7/1892; C08G 77/24; C08G 77/80; C08G 77/08; G03F 7/0757; G03F 7/2004

(57) ABSTRACT

There is provided a silicon compound represented by General Formula (x). There is also provided a reactive material containing a silicon compound represented by General Formula (x). In General Formula (x), in a case where a plurality of R¹'s are present, R¹'s are each independently a linear alkyl group having 1 to 10 carbon atoms, a branched alkyl group having 3 to 10 carbon atoms, a cyclic alkyl group having 3 to 10 carbon atoms, a linear alkenyl group having 2 to 10 carbon atoms, a branched alkenyl group having 3 to 10 carbon atoms, or a cyclic alkenyl group having 3 to 10 carbon atoms, where all or part of hydrogen atoms in the alkyl group or the alkenyl group may be substituted with a fluorine atom, in a case where a plurality of R²'s are present, R²'s are each independently a linear alkyl group having 1 to 4 carbon atoms or a branched alkyl group having 3 or 4 carbon atoms, where all or part of hydrogen atoms in the alkyl group may be substituted with a fluorine atom, R^{A} is an acid unstable group; a is an integer of 1 to 3, b is an integer of 0 to 2, and c is an integer of 1 to 3, where a+b+c=4 is satisfied; and n is an integer of 1 to 5.

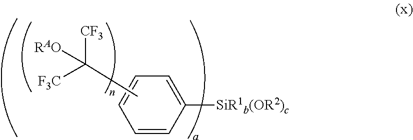

### TECHNICAL FIELD

The present invention relates to a silicon compound, a reactive material, a resin composition, a photosensitive resin composition, a cured film, a method of manufacturing cured film, a patterned cured film, and a method of manufacturing patterned cured film.

### BACKGROUND ART

High molecular-weight compounds containing siloxane bonds have high heat resistance and transparency. Based on these characteristics, attempts have been made to apply high molecular-weight compounds containing siloxane bonds to, for example, coating materials for liquid crystal displays and organic EL displays, coating agents for image sensors, sealing materials in the field of semiconductors, photosensitive resin compositions, and the like.

In addition, high molecular-weight compounds containing siloxane bonds have high oxygen plasma resistance. For this reason, high molecular-weight compounds containing siloxane bonds are also being studied, for example, as hard mask materials for a multilayer resist.

Patent Document 1 discloses a positive photosensitive resin composition containing a polysiloxane compound having a structure in which a benzene ring is substituted with a group represented by —C(CF₃)₂OX (X is a hydrogen atom or an acid unstable group).

In paragraph 0106 and Example 3-1 of this Patent Document 1, as a method of synthesizing a polysiloxane compound, it is described that di-tert-butyl dicarbonate is reacted with a polysiloxane compound (a polymer) having a group represented by —C(CF₃)₂OH to introduce an acid unstable group (a t-butoxycarbonyl group) into the polymer.

Patent Document 2 discloses a production method including two specific steps, as a method of producing a siloxane compound having a structure in which a group represented by —C(CF₃)₂OH is substituted in a benzene ring.

### RELATED DOCUMENT

### Patent Document

[Patent Document 1] Japanese Patent No. 6323225
[Patent Document 2] International Publication No. WO2019/167770

### SUMMARY OF THE INVENTION

### Technical Problem

While carrying out studies on the fluorine-containing siloxane compound, the inventors of the present invention found that the fluorine-containing siloxane compounds in the related art have room for improvement, for example, in terms of storage stability.

Then, the inventors of the present invention carried out various studies to provide a fluorine-containing siloxane compound having good storage stability as one of the purposes of the studies.

### Solution to Problem

As a result of the studies, the present inventors completed the invention provided below, thereby solving the problems described above.

The present invention is represented as follows.

1. A silicon compound represented by General Formula (x).

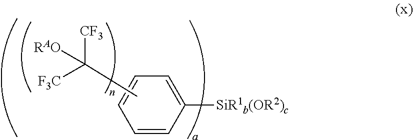

In General Formula (x),

in a case where a plurality of R¹'s are present, R¹'s each are independently a linear alkyl group having 1 to 10 carbon atoms, a branched alkyl group having 3 to 10 carbon atoms, a cyclic alkyl group having 3 to 10 carbon atoms, a linear alkenyl group having 2 to 10 carbon atoms, a branched alkenyl group having 3 to 10 carbon atoms, or a cyclic alkenyl group having 3 to 10 carbon atoms, where all or part of hydrogen atoms in the alkyl group or the alkenyl group may be substituted with a fluorine atoms,

in a case where a plurality of R²'s are present, R²'s are each independently a linear alkyl group having 1 to 4 carbon atoms or a branched alkyl group having 3 or 4 carbon atoms, where all or part of hydrogen atoms in the alkyl group may be substituted with a fluorine atom,

R^{A} is an acid unstable group,

a is an integer of 1 to 3, b is an integer of 0 to 2, and c is an integer of 1 to 3, where a+b+c=4 is satisfied, and

n is an integer of 1 to 5.

2. The silicon compound according to 1.,

in which the R^{A} is at least any group selected from the group consisting of an alkyl group, an alkoxycarbonyl group, an acetal group, a silyl group, and an acyl group.

3. A reactive material containing a silicon compound (X) represented by General Formula (x).

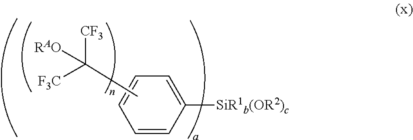

In General Formula (x),

in a case where a plurality of R¹'s are present, R¹'s each are independently a linear alkyl group having 1 to 10 carbon atoms, a branched alkyl group having 3 to 10 carbon atoms, a cyclic alkyl group having 3 to 10 carbon atoms, a linear alkenyl group having 2 to 10 carbon atoms, a branched alkenyl group having 3 to 10 carbon atoms, or a cyclic alkenyl group having 3 to 10 carbon atoms, where all or part of hydrogen atoms in the alkyl group or the alkenyl group may be substituted with a fluorine atoms,

in a case where a plurality of R²'s are present, R²'s are each independently a linear alkyl group having 1 to 4 carbon atoms or a branched alkyl group having 3 or 4 carbon atoms, where all or part of hydrogen atoms in the alkyl group may be substituted with a fluorine atom,

R^{A} is an acid unstable group,

a is an integer of 1 to 3, b is an integer of 0 to 2, and c is an integer of 1 to 3, where a+b+c=4 is satisfied, and

n is an integer of 1 to 5.

4. The reactive material according to 3,

in which the R^{A} is at least any group selected from the group consisting of an alkyl group, an alkoxycarbonyl group, an acetal group, a silyl group, and an acyl group.

5. The reactive material according to 3 or 4, further containing:

a silicon compound (Y) represented by General Formula (y),

in which in a case where a mass of the silicon compound (X) contained in the reactive material is denoted by M_{X} and a mass of the silicon compound (Y) contained in the reactive material is denoted by M_{Y}, a ratio of the silicon compound (Y), represented by {M_{Y}/(M_{X}+M_{y})}×100, is 1×10⁻⁴% to 12% by mass.

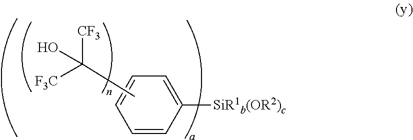

In General Formula (y), definitions of R¹, R², a, b, c, and n are respectively the same as those in General Formula (x).

6. A polysiloxane compound, in which the polysiloxane compound is obtained by polycondensing the silicon compound according to 1 or 2 or the reactive material according to any one of 3 to 5 in a presence of an acidic catalyst or a basic catalyst.

7. The polysiloxane compound according to 6,

in which a weight average molecular weight of the polysiloxane compound is 1,000 to 100,000.

8. A resin composition containing the polysiloxane compound according to 6 or 7, and a solvent.

9. The resin composition according to 8,

in which the solvent includes at least one selected from the group consisting of propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols, glycol ethers, and glycol ether esters.

10. A photosensitive resin composition containing the resin composition according to 8 or 9 and a photoacid generator.

11. A cured film of the resin composition according to 8 or 9.

12. A method of manufacturing a cured film, including a heating step of applying the resin composition according to 8 or 9 onto a base material and then carrying out heating at a temperature of 100° C. to 350° C.

13. A patterned cured film of the photosensitive resin composition according to 10.

14. A method of manufacturing a patterned cured film, including a film forming step of applying the photosensitive resin composition according to 10 onto a base material to form a photosensitive resin film,

an exposure step of exposing the photosensitive resin film,

a developing step of developing the exposed photosensitive resin film to form a patterned resin film, and

a curing step of heating the patterned resin film to make the patterned resin film into a patterned cured film.

15. The method of manufacturing a patterned cured film according to 14,

in which a wavelength of light that is used for the exposure in the exposure step is 100 to 600 nm.

### Advantageous Effects of Invention

According to the present invention, a fluorine-containing siloxane compound having good storage stability is provided.

### DESCRIPTION OF EMBODIMENTS

Hereinafter, embodiments of the present invention will be described in detail.

In the present specification, the description “X to Y” in the description of a numerical range represents X or more and Y or less unless specified otherwise. For example, “1% to 5% by mass” means “1% by mass or more and 5% by mass or less”.

In the present specification, the description “group (atomic group)” includes both a group not having a substituent and a group having a substituent unless specified that the group is substituted or unsubstituted. For example, “alkyl group” includes not only an alkyl group not having a substituent (an unsubstituted alkyl group) but also an alkyl group having a substituent (a substituted alkyl group).

In the present specification, the “cyclic alkyl group” includes not only a monocyclic structure but also a polycyclic structure. The same applies to the “cycloalkyl group”.

The description “(meth)acryl” in the present specification represents a concept including both acryl and methacryl. The same applies to the similar description such as “(meth)acrylate”.

Unless otherwise specified, the term “organic group” in the present specification means an atomic group obtained by removing one or more hydrogen atoms from an organic compound. For example, the “monovalent organic group” represents an atomic group obtained by removing one hydrogen atom from any organic compound.

In the present specification, the group represented by —C(CF₃)₂OH may be referred to as an “HFIP group” by taking the acronym for hexafluoroisopropanol group.

<Silicon Compound and Reactive Material>

A silicon compound (a silicon compound (X)) of the present embodiment is represented by General Formula (x).

Further, a reactive material of the present embodiment contains a silicon compound (X) represented by General Formula (x).

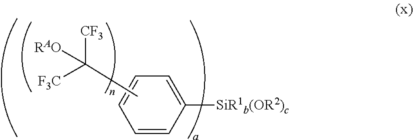

In General Formula (x),

in a case where a plurality of R¹'s are present, R¹'s each are independently a linear alkyl group having 1 to 10 carbon atoms, a branched alkyl group having 3 to 10 carbon atoms, a cyclic alkyl group having 3 to 10 carbon atoms, a linear alkenyl group having 2 to 10 carbon atoms, a branched alkenyl group having 3 to 10 carbon atoms, or a cyclic alkenyl group having 3 to 10 carbon atoms, where all or part of hydrogen atoms in the alkyl group or the alkenyl group may be substituted with a fluorine atoms,

in a case where a plurality of R²'s are present, R²'s are each independently a linear alkyl group having 1 to 4 carbon atoms or a branched alkyl group having 3 or 4 carbon atoms, where all or part of hydrogen atoms in the alkyl group may be substituted with a fluorine atom,

R^{A} is an acid unstable group,

a is an integer of 1 to 3, b is an integer of 0 to 2, and c is an integer of 1 to 3, where a+b+c=4 is satisfied, and

n is an integer of 1 to 5.

In the silicon compound (X), the hydrogen atom (exhibiting acidity) of the HFIP group is protected by an acid unstable group. As a result, it is conceived that the hydrolysis or polycondensation of the —SiR¹_{b}(OR²)_{c} moiety in General Formula (x) can be suppressed, and good storage stability can be obtained. Good storage stability is a highly desirable property in the industrial use of chemical materials.

Hereinafter, the silicon compound (X) and the reactive material of the present embodiment will be described in more detail.

(About General Formula (x))

In terms of availability of raw materials and cost, R¹ is preferably an alkyl group having 1 to 6 carbon atoms and more preferably a methyl group.

Similarly, in terms of availability of raw materials and cost, R² is preferably a methyl group or an ethyl group.

In terms of ease of synthesis, a is preferably 1.

Similarly, in terms of ease of synthesis, n is preferably 1 or 2 and more preferably 1.

c is preferably 2 or 3. In a case where two or more OR²'s are present, it is possible to produce a polysiloxane compound (a polymer or an oligomer) using the silicon compound (X).

In relation to the reactivity (the orientation) of the benzene ring, the group represented by —C(CF₃)₂OR^{A} is preferably present at the meta position with respect to the group represented by —SiR¹_{b} (OR²)_{c}. More specifically, the moiety of the following group (2) in General Formula (x) can be any one of the structures represented by Formula (2A) to Formula (2D); however, among them, it is preferably a structure represented by Formula (2A) or a structure represented by Formula (2D).

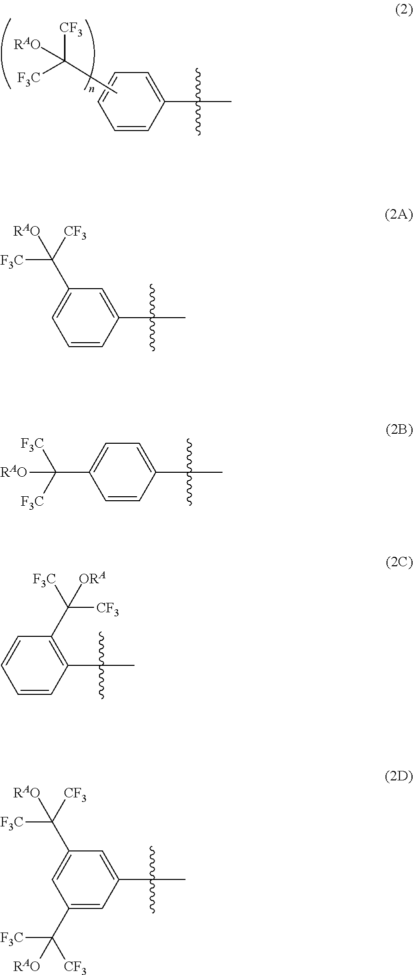

In the group (2) and Formula (2A) to Formula (2D), a wavy line indicates that the intersecting line segment corresponds to a bond.

Examples of the acid unstable group as R^{A} include those known as acid unstable groups in the field of photosensitive resin compositions without particular limitation. For example, examples of the acid unstable group include an alkyl group, an alkoxycarbonyl group, an acetal group, a silyl group, and an acyl group.

Examples of the alkyl group include a tert-butyl group, a tert-amyl group, a 1,1-dimethylpropyl group, a 1-ethyl-1-methylpropyl group, a 1,1-dimethylbutyl group, an allyl group, a 1-pyrenylmethyl group, a 5-dibenzosveryl group, a triphenylmethyl group, a 1-ethyl-1-methylbutyl group, a 1,1-diethylpropyl group, a 1,1-dimethyl-1-phenylmethyl group, a 1-methyl-1-ethyl-1-phenylmethyl group, a 1,1-diethyl-1-phenylmethyl group, a 1-methylcyclohexyl group, a 1-ethylcyclohexyl group, a 1-methylcyclopentyl group, a 1-ethylcyclopentyl group, a 1-isobornyl group, a 1-methyladamantyl group, a 1-ethyl adamantyl group, a 1-isopropyladamantyl group, a 1-isopropylnorbornyl group, and a 1-isopropyl-(4-methylcyclohexyl) group. The alkyl group is preferably a tertiary alkyl group, more preferably a group represented by —CR^{p}R^{q}R^{r} (R^{p}, R^{q}, and R^{r} are each independently a linear or branched alkyl group, a monocyclic or polycyclic cycloalkyl group, an aryl group, or an aralkyl group, and two of R^{p}, R^{q}, and R^{r} may be bonded to form a ring structure).

Examples of the alkoxycarbonyl group include a tert-butoxycarbonyl group, a tert-amyloxycarbonyl group, a methoxycarbonyl group, an ethoxycarbonyl group, and an i-propoxycarbonyl group.

Examples of the acetal group include a methoxymethyl group, an ethoxyethyl group, a butoxyethyl group, a cyclohexyloxyethyl group, a benzyloxyethyl group, a phenethyloxyethyl group, an ethoxypropyl group, a benzyloxypropyl group, a phenethyloxypropyl group, an ethoxybutyl group, and an ethoxyisobutyl group.

Examples of the silyl group include a trimethylsilyl group, an ethyldimethylsilyl group, a methyldiethylsilyl group, a triethylsilyl group, an i-propyldimethylsilyl group, a methyldi-i-propylsilyl group, a tri-i-propylsilyl group, a tert-butyldimethylsilyl group, a methyldi-tert-butylsilyl group, a tri-tert-butylsilyl group, a phenyldimethylsilyl group, a methyldiphenylsilyl group, and a triphenylsilyl group.

Examples of the acyl group include, an acetyl group, a propionyl group, a butyryl group, a heptanoyl group, a hexanoyl group, a valeryl group, a pivaloyl group, an isovaleryl group, a laurylloyl group, amyritoyl group, apalmitoyl group, a stearoyl group, anoxalyl group, a malonyl group, a succinyl group, a glutalyl group, an adipoil group, a piperoyl group, a suberoyl group, an azelaoyl group, a sebacoil group, a (meth) acryloyl group, a propioloyl group, a crotonoyle group, anoleoyl group, amaleoyl group, a fumaroyl group, amesaconoyl group, a camphoroyl group, a benzoyl group, a phthaloyl group, an isophthaloyl group, a terephthaloyl group, a naphthoyl group, a toluoyl group, a hydroatropoyl group, an atropoyl group, a cinnamoyl group, a floyl group, a tenoyl group, a nicotinoyl group, an isonicotinoyl group.

A part or all of hydrogen atoms of the acid unstable group may be substituted with a fluorine atom.

Examples of the particularly preferred structure of the R^{A} include a structure represented by Formula (ALG-1) and a structure represented by Formula (ALG-2).

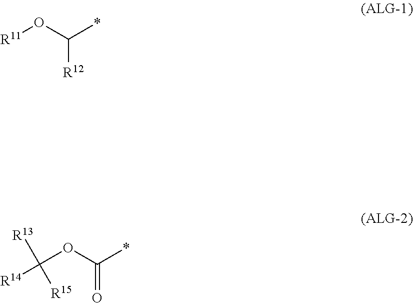

In General Formula (ALG-1),

R¹¹ is a linear alkyl group having 1 to 10 carbon atoms, a branched alkyl group having 3 to 10 carbon atoms, or a cyclic alkyl group having 3 to 10 carbon atoms, an aryl group having 6 to 20 carbon atoms, or an aralkyl group having 7 to 21 carbon atoms, and

R¹² is a hydrogen atom, a linear alkyl group having 1 to 10 carbon atoms, a branched alkyl group having 3 to 10 carbon atoms, or a cyclic alkyl group having 3 to 10 carbon atoms, an aryl group having 6 to 20 carbon atoms, or an aralkyl group having 7 to 21 carbon atoms.

In General Formula (ALG-2),

R¹³, R¹⁴, and R¹⁵ are each independently a linear alkyl group having 1 to 10 carbon atoms, a branched alkyl group having 3 to 10 carbon atoms, or a cyclic alkyl group having 3 to 10 carbon atoms, an aryl group having 6 to 20 carbon atoms, or an aralkyl group having 7 to 21 carbon atoms, and

two of R¹³, R¹⁴, and R¹⁵ may be bonded to each other to form a ring structure.

In General Formula (ALG-1) and General Formula (ALG-2), * represents a bonding site to an oxygen atom.

In a case where n is 2 or more in General Formula (x), one molecule of the silicon compound (X) has 2 or more R^{A}'s. In this case, the two or more R^{A}'s may be the same or different from each other.

Further, the reactive material of the present embodiment may contain two or more kinds of silicon compounds (X) having R^{A}'s that have chemical structures different from each other. Needless to say, the reactive material of the present embodiment may contain substantially only one kind of silicon compound (X).

Specific examples of the silicon compound (X) are exemplified below.

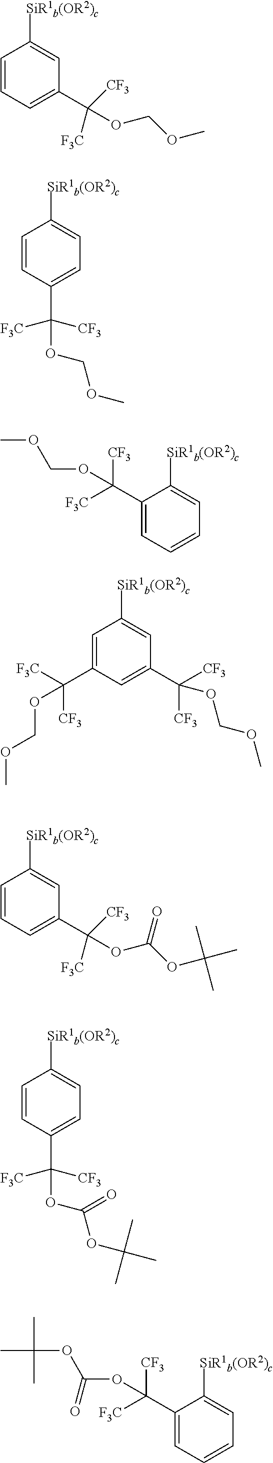

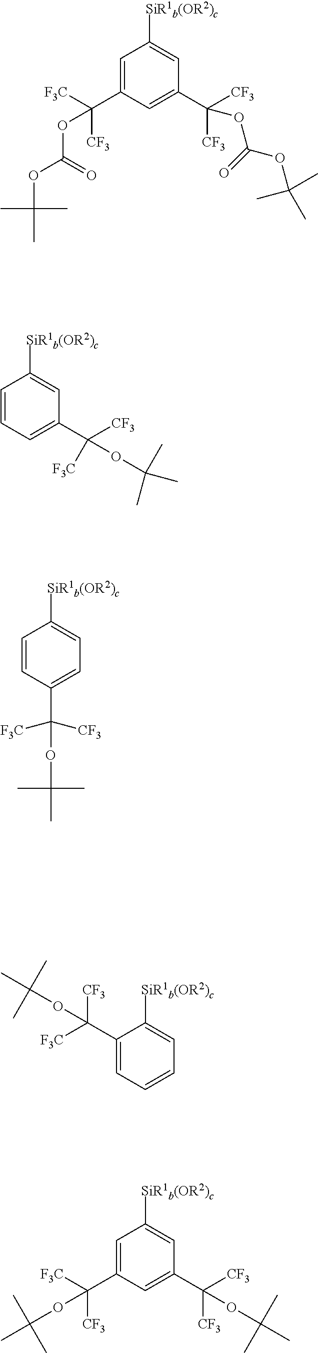

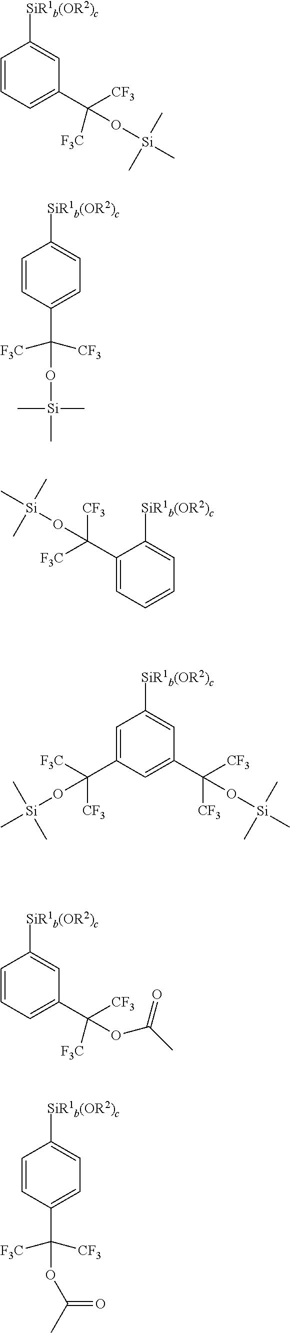

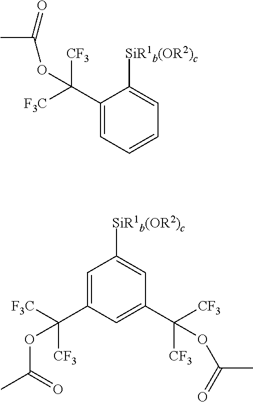

In each of the above specific examples, the combination of R¹, R², b, and c is, for example, any one of the combinations 1 to 6 shown in Table 1 below. In Table 1, Me represents a methyl group, and Et represents an ethyl group.

TABLE 1

| Combination | R¹ | b | R² | c |
|---|---|---|---|---|
| 1 | — | 0 | Et | 3 |
| 2 | Me | 1 | Et | 2 |
| 3 | Me | 2 | Et | 1 |
| 4 | — | 0 | Me | 3 |
| 5 | Me | 1 | Me | 2 |
| 6 | Me | 2 | Me | 1 |

(About Silicon Compound (Y))

The reactive material of the present embodiment can further contain a silicon compound (Y) represented by General Formula (y). Here, in a case where the mass of the silicon compound (X) contained in the reactive material is denoted by M_{X} and the mass of the silicon compound (Y) contained in the reactive material is denoted by M_{Y}, the ratio (% by mass) of the silicon compound (Y), represented by {M_{Y}/(M_{X}+M_{Y})}×100 is preferably 1×10⁻⁴% to 12%, more preferably 5×10⁻⁴% to 10%, still more preferably 0.001% to 8%, and particularly preferably 0.01% to 5%.

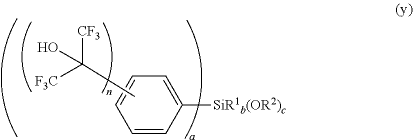

In General Formula (y), the definitions and preferred aspects of R¹, R², a, b, c, and n are the same as those in General Formula (x).

The silicon compound (Y) has an HFIP group that is not protected by an acid unstable group. As a result, the silicon compound (Y) exhibits acidity. It is conceived that since an appropriate amount of the acidic silicon compound (Y) is contained in the reactive material, the effect of storage stability is obtained and the effect of good reactivity is also obtained.

As an acid catalyst, the silicon compound (Y) is conceived to contribute to the reaction of the silicon compound (X), for example, polycondensation (formation of a siloxane bond by dehydration). As a result, in a case where an appropriate amount of the silicon compound (Y) is contained in the reactive material of the present embodiment, it is conceived that good polymerizability can be obtained while the effect of storage stability is obtained, for example, in a case where the reactive material of the present embodiment is used as a raw material monomer of the polysiloxane compound. Further, it is conceived that good adhesiveness and curability are exhibited while the effect of storage stability is obtained, for example, in a case where the reactive material of the present embodiment is used as a primer.

Further, it is conceived that the silicon compound (Y) is incorporated into a polysiloxane compound to be produced, for example, in a case where the reactive material of the present embodiment is used as a raw material monomer of the polysiloxane compound. This is conceived to lead to the advantage that the catalyst does not need to be removed after the synthesis of the polysiloxane compound.

(Silicon Compound (X)/Method of Producing Reactive Material)

A method of producing the silicon compound (X)/reactive material of the present embodiment is not particularly limited. A typical production method will be described below.

First, a compound which corresponds to a compound represented by General Formula (x) in which R^{A} is a hydrogen atom is prepared. Such a compound is known and can be synthesized, for example, with reference to the method disclosed in Patent Document 2 described above.

Next, an acid unstable group is introduced into the compound which corresponds to a compound represented by General Formula (x) in which R^{A} is a hydrogen atom. As a method of introducing an acid unstable group, a known method of introducing an acid unstable group into an alcohol compound can be adopted.

For example, it is possible to introduce an acid unstable group by reacting a dialkyl ecarbonate compound or alkoxycarbonylalkyl halide with a compound which corresponds to a compound represented by General Formula (x) in which R^{A} is a hydrogen atom in a solvent in the presence of a base.

As an example of the method of introducing an acid unstable group, a method of introducing a tert-butoxycarbonyl group (a group represented by General Formula (ALG-2) in which R¹³, R¹⁴, and R¹⁵ are a methyl group) which can be easily deprotected by heat treatment and is preferably used, will be described.

To a molar amount of the HFIP group present in the molecule of the compound which corresponds to a compound represented by General Formula (x) in which R^{A} is a hydrogen atom, the same molar amount or more of di-tert-butyl ecarbonate is added, dissolved in a solvent and reacted in the presence of a base such as pyridine, triethylamine, or N,N-dimethylaminopyridine. In this manner, the tert-butoxycarbonyl group can be introduced. The solvent that can be used is not particularly limited as long as it can dissolve the compound to be charged to the above reaction system and does not adversely affect the reaction. Specifically, toluene, xylene, pyridine, or the like is preferable. The reaction temperature and the reaction time vary depending on the kind of base to be used or the like; however, in general, the reaction temperature is room temperature or higher and 180° C. or lower, and the reaction time is 1 to 24 hours. After completion of the reaction, a silicon compound (X) which corresponds to a compound represented by General Formula (x) in which R^{A} is a tert-butoxycarbonyl group can be obtained by distilling off a solvent, a base, and di-tert-butyl ecarbonate in a case where an excess amount of di-tert-butyl ecarbonate is added.

As another example of the method of introducing an acid unstable group, a method of introducing a methoxymethyl group (a group which corresponds to a group represented by General Formula (ALG-1) in which R¹¹ is a methyl group and R¹² is a hydrogen atom) will be described.

To a molar amount of the HFIP group present in the molecule of the compound which corresponds to a compound represented by General Formula (x) in which R^{A} is a hydrogen atom, the same molar amount or more of a strong base (NaH or the like) and the same molar amount or more of chloromethyl methyl ether are added and reacted. In this manner, the methoxymethyl group can be introduced. The solvent that can be used at this time is not particularly limited, and any solvent that can dissolve the compound to be charged to the reaction system and does not adversely affect the reaction can be used. The preferred solvent is tetrahydrofuran or the like. The reaction proceeds even at room temperature. After the reaction is completed, as post-treatment, it is preferable to carry out charging of a solvent (toluene, diisopropyl ether, or the like) for two layer separation at the time of washing with water, washing with water, washing with a saline solution, simple distillation (pressure: about 2.5 kPa, temperature: about 200 to 220° C.), or the like.

As still another example of the method of introducing an acid unstable group, a method of introducing an acid unstable group by using a vinyl acetal will be described.

With a molar amount of the HFIP group present in the molecule of the compound which corresponds to a compound represented by General Formula (x) in which R^{A} is a hydrogen atom, the same molar amount or more of vinyl acetal (a compound represented by R¹¹—O—CH═CH₂, the definition of R¹¹ is the same as that in General Formula (ALG-1)) is reacted in the presence of an acid catalyst (for example, paratoluenesulfonic acid). This makes it possible to introduce an acid unstable group which corresponds to a group represented by General Formula (ALG-1) in which R¹² is a methyl group. The solvent that can be used at this time is not particularly limited, and any solvent that can dissolve the compound to be charged to the reaction system and does not adversely affect the reaction can be used. The reaction proceeds even at room temperature. After completion of the reaction, post-treatment such as washing or distillation may be carried out.

<Polysiloxane Compound and Production Method Thereof>

The polysiloxane compound of the present embodiment is produced by polycondensing the above-described silicon compound (the silicon compound (X)) or the above-described reactive material in the presence of an acidic catalyst or a basic catalyst. In the silicon compound (X), the “OR²” moiety in General Formula (x) is hydrolyzed in the presence of an acidic catalyst or abasic catalyst. As a result, a silanol group is generated. In a case where two or more of the generated silanol groups undergo dehydration condensation, a polysiloxane compound is obtained. Alternatively, a polysiloxane compound can also be obtained by a condensation reaction between the generated silanol group and the “Si—OR²” moiety.

At the time of polycondensation, a reactive material (a monomer) different from the silicon compound (X) or the silicon compound (Y) may be allowed to be present in the reaction system. This makes it possible to obtain a copolymer. This will be described later.

Examples of the method of producing a polysiloxane compound having a structure in which an HFIP group is protected by an acid unstable group include the following two production methods.
Production method 1: A reactive material having an unprotected HFIP group (for example, a compound which corresponds to a compound represented by General Formula (x) in which R^{A} is a hydrogen atom) is polycondensed to obtain a polymer or an oligomer. Then, an acid unstable group is introduced into the polymer or the oligomer.
Production method 2: A reactive material in which an HFIP group is protected in advance with an acid unstable group, such as the silicon compound (X), is polycondensed.

In Example 3-1 of Patent Document 1 described above, a polysiloxane compound having an acid unstable group is produced as in the “production method 1” described above. However, according to the findings of the inventors of the present invention, there were problems, for example, that in a case where a polysiloxane compound is produced as in Production Method 1, an undesired by-product is generated, the final product is colored, and a polysiloxane compound having a large weight average molecular weight is hardly produced.

The inventors of the present invention have carried out various studies to solve the above problems. Through the studies, it was surprisingly found that the above problems hardly occur in a case where a polysiloxane compound is produced as in the production method 2.

It was not necessarily clear how the polysiloxane compound produced according to the production method 1 and the polysiloxane compound produced according to the production method 2 are different as a product. However, the inventors of the present invention have obtained the finding that the polysiloxane compound produced according to the production method 1 and the polysiloxane compound produced according to the production method 2 seem to be different from each other, for example, in terms of transparency.

Although it is only a guess, as the cause of the difference between the polysiloxane compound produced according to the production method 1 and the polysiloxane compound produced according to the production method 2 as a product, the following is conceived to be involved, for example; (1) the unprotected HFIP group that deactivates the polymerization catalyst (particularly the basic catalyst) in the case of the production method 1, and (2) unintended by-products are likely to be generated and it may be difficult to remove the by-products in the case of the production method 1.

To supplement the above (2), it is easy to remove impurities (unreacted substances and the like) by introducing an acid unstable group into the monomer of the raw material before the production of the polysiloxane compound as in the production method 2 as compared with the production method 1, which is conceived to lead to an increase in the transparency of the final polysiloxane compound. That is, in a case where the above-described silicon compound (the silicon compound (X)) or the above-described reactive material is subjected to polycondensation in the presence of an acidic catalyst or a basic catalyst, a highly transparent polysiloxane compound is easily obtained.

According to the findings of the inventors of the present invention, there is a tendency that a polysiloxane compound having a large weight average molecular weight can be obtained by producing the polysiloxane compound according to the production method 2 as compared with the production of the polysiloxane compound according to the production method 1. In other words, it can be said that the reactive material containing the silicon compound (X) of the present embodiment has good reactivity in that a polysiloxane compound having a larger weight average molecular weight and having good storage stability can be obtained.

The weight average molecular weight of the polysiloxane compound of the present embodiment is preferably 1,000 to 100,000 and more preferably 1,500 to 50,000. As described above, there is a tendency that a polysiloxane compound having a relatively large weight average molecular weight can be obtained by using the reactive material of the present embodiment as a raw material and polycondensing this raw material in the presence of an acidic catalyst or a basic catalyst.

As for the polycondensation procedure and the reaction conditions in producing the polysiloxane compound of the present embodiment, it is possible to appropriately apply known techniques in hydrolysis and condensation reactions of an alkoxysilane. As an example, it is possible to produce the polysiloxane compound of the present embodiment under the procedures and conditions as described in (1) to (4) below.

(1) First, a predetermined amount of the above-described reactive material is collected in a reaction container at room temperature (particularly refers to an ambient temperature without heating or cooling and generally about 15° C. to 30° C.).

(2) Water for hydrolysis, a catalyst for allowing the polycondensation reaction to proceed, and a reaction solvent as desired are added to the reaction container and appropriately stirred to prepare a reaction solution. The order of charging the above substances is not limited to the order described above, and they can be charged in any order to prepare the reaction solution. At this time, a siloxane compound (a monomer) that does not correspond to the silicon compound (X) or silicon compound (Y) may be added to the reaction container. This makes it possible to produce a polysiloxane compound which is a copolymer.

(3) The hydrolysis and condensation reactions are allowed to proceed while stirring the reaction solution prepared in the (2). Although being dependent on the kind of catalyst, the time required for the reaction is usually 3 to 24 hours, and the reaction temperature is usually room temperature (25° C.) to 200° C. In a case of carrying out heating, the reaction container is preferably to be a closed type or it is preferable to reflux the reaction system by attaching a reflux device such as a condenser to prevent unreacted raw materials, water, a reaction solvent, and/or a catalyst in the reaction system from being distilled off out of the reaction system.

(4) Preferably, after the reaction is completed, the water remaining in the reaction system, generated alcohol, the catalyst, and the like are removed. The water, the alcohol, and the catalyst may be removed by extraction, or a solvent such as toluene that does not adversely affect the reaction may be added into the reaction system and azeotropically removed by using a Dean-Stark tube.

The amount of water that is used in the hydrolysis and condensation reactions is not particularly limited. From the viewpoint of reaction efficiency, it is preferably 0.5 to 5 times the total number of moles of ecarbonate groups (such as OR² in General Formula (x)) contained in the raw material.

There is no particular limitation on the catalyst for allowing polycondensation to proceed. A catalyst known as the acid catalyst or base catalyst can be appropriately used.

Examples of the acid catalyst include hydrochloric acid, nitric acid, sulfuric acid, fluoric acid, phosphoric acid, acetic acid, oxalic acid, trifluoroacetic acid, methanesulfonic acid, trifluoromethanesulfonic acid, camphorsulfonic acid, benzenesulfonic acid, tosylic acid, formic acid, a polyvalent carboxylic acid, and an anhydride thereof.

Examples of the base catalyst include tetramethylammonium hydroxide, triethylamine, tripropyl amine, tributyl amine, tripentyl amine, trihexyl amine, triheptyl amine, trioctyl amine, diethylamine, triethanol amine, diethanol amine, sodium hydroxide, potassium hydroxide, and sodium carbonate.

The using amount of the catalyst is preferably 1.0×10⁻⁵ to 1.0×10⁻¹ times the total number of moles of ecarbonate groups (such as OR² in General Formula (x)) contained in the raw material.

In producing the polysiloxane compound, a reaction solvent may be or may not be used.

In a case where a reaction solvent is used, the kind thereof is not particularly limited. A polar solvent is preferable and an alcohol solvent is more preferable, from the viewpoint of solubility of a raw material compound, water, and a catalyst. Specific examples thereof include methanol, ethanol, 1-propanol, 2-propanol, 1-butanol, 2-butanol, diacetone alcohol, and propylene glycol monomethyl ether. The reaction solvent may be a single solvent or a mixed solvent. In a case where a reaction solvent is used, the using amount thereof may be any amount that is necessary for the reaction to proceed in a uniform system.

(Copolymerization Component (Silicon Compound (Z))

As described above, at the time of polycondensation, one or two or more kinds of reactive materials (monomers) different from the silicon compound (X) or silicon compound (Y) may be allowed to be present in the reaction system to obtain a copolymer. Specifically, in the above procedure (2), a copolymer can be obtained by adding a siloxane compound that does not correspond to the silicon compound (X) or silicon compound (Y) or a silane compound monomer into the reaction container.

Hereinafter, “the siloxane compound that does not correspond to the silicon compound (X) or silicon compound (Y) or the silane compound monomer” is also collectively denoted as “silicon compound (Z)”.

Preferred examples of the silicon compound (Z) include a compound having, in the molecule, (i) a ecarbonate alkoxysilyl group and (ii) at least any group selected from the group consisting of an epoxy group, an oxetane group, and a (meth)acryloyl group (hereinafter, this compound is also referred to as a silicon compound (Z1)).

In a case where a structural unit derived from the silicon compound (Z1) is incorporated into the polysiloxane compound of the present embodiment, for example, the polysiloxane compound of the present embodiment can be preferably applied to a thermosetting resin composition or the like.

More specifically, the silicon compound (Z1) is represented by General Formula (z1).

(R^{y} [symbol] ₐSiR¹_{b}(OR²)_{c} (z1)

In General Formula (z1),

The definitions and preferred aspects of R¹, R², a, b, and c are the same as those in General Formula (x),

R^{y} is a monovalent organic group having 2 to 30 carbon atoms, which contains any one of an epoxy group, an oxetane group, and a (meth)acryloyl group.

In a case where R^{y} contains an epoxy group or an oxetane group, for example, it is possible to enhance the adhesiveness to various base materials such as silicon, glass, and resin in a case where the polysiloxane compound of the present embodiment is applied to a resin composition described later. Further, in a case where R^{y} contains a (meth)acryloyl group, for example, it is possible to obtain good solvent resistance in a case where the polysiloxane compound of the present embodiment is used as a cured film described later.

In a case where R^{y} contains an epoxy group or an oxetane group, R^{y} is preferably a group represented by Formula (2a), (2b), or (2c) below.

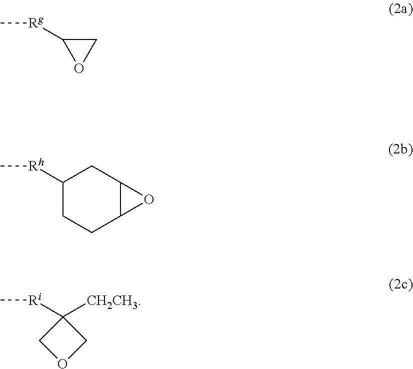

In the formulae, R^{g}, R^{h}, and Rⁱ each independently represent a single bond or a divalent organic group. Broken lines represent a bond. In a case where R^{g}, R^{h}, and Rⁱ are divalent organic groups, examples of the divalent organic group include an alkylene group having 1 to 20 carbon atoms. This alkylene group may contain one or more moieties in which an ether bond is formed. In a case where the number of carbon atoms is 3 or more, the alkylene group may be branched, or carbons spaced apart from each other may be connected to each other to form a ring. In a case where two or more alkylene groups are present, one or more moieties in which an ether bond is formed by inserting oxygen between carbons may be contained.

In a case where R^{y} contains a (meth)acryloyl group, R^{y} is preferably a group selected from Formula (3a) or (4a) below.

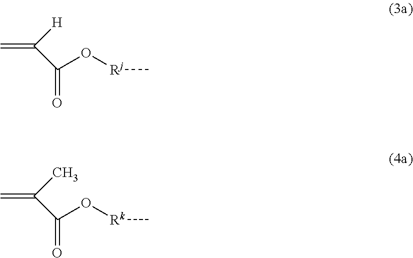

In the formulae, R^{j} and R^{k} each independently represent a single bond or a divalent organic group. Broken lines represent a bond.

In where R^{j} and R^{k} are a divalent organic group, preferred examples thereof include those exemplified above as the preferred groups in R^{g}, R^{h}, and Rⁱ.

Specific examples of the silicon compound (Z1) include 3-glycidoxypropyltrimethoxysilane (manufactured by Shin-Etsu Chemical Co., Ltd., product name: KBM-403), 3-glysidoxypropyltriethoxysilane (same as above, product name: KBE-403), 3-glycidoxypropylmethyldiethoxysilane (same as above, product name: KBE-402), 3-glycidoxypropylmethyldimethoxysilane (same as above, product name: KBM-402), 2-(3,4-epylcyclohexyl)ethyltrimethoxysilane (same as above, product name: KBM-303), 2-(3,4-epylcyclohexyl) ethyltriethoxysilane, 8-glycidoxyoctyltrimethoxysilane (same as above, product name: KBM-4803), [(3-ethyl-3-oxetanyl)methoxy]propyltrimethoxysilane, and [(3-ethyl-3-oxetanyl)methoxy]propyltriethoxysilane.

In addition, specific examples of the silicon compound (Z1) also include 3-methacryloxypropyltrimethoxysilane (manufactured by Shinetsu Chemical Industry Co., Ltd., product name: KBM-503). 3-methacryloxypropyltriethoxysilane (same as above, product name: KBE-503), 3-methacryloxypropylmethyldimethoxysilane (same as above, product name: KBM-502), 3-methacryloxypropylmethyldiethoxysilane (same as above, product name: KBE-502), 3-acryloxypropyltrimethoxysilane (same as above, product name: KBM-5103), and 8-methacryloxyoctyltrimethoxysilane (same as above, product name: KBM-5803).

Other examples of the silicon compound (Z) include a tetraalkoxysilane, a tetrahalosilane, and an oligomer thereof. Examples of the oligomer include Silicate 40 (a pentamer on average, manufactured by Tama Chemicals Co., Ltd.), Ethyl silicate 40 (a pentamer on average, manufactured by Colcoat Co., Ltd.), Silicate 45 (a heptamer on average, manufactured by Tama Chemicals Co., Ltd.), M silicate 51 (a tetramer on average, manufactured by Tama Chemicals Co., Ltd.), Methyl silicate 51 (a tetramer on average, manufactured by Colcoat Co., Ltd.), Methyl silicate 53A (a heptamer on average, manufactured by Colcoat Co., Ltd.), Ethyl silicate 48 (a decamer on average, manufactured by Colcoat Co., Ltd.), and EMS-485 (a mixture of ethyl silicate and methyl silicate, manufactured by Colcoat Co., Ltd.).

Still other examples of the silicon compound (Z) include various alkoxysilanes. Specific examples thereof include dimethyldimethoxysilane, dimethyldiethoxysilane, dimethyldipropoxysilane, dimethyldiphenoxysilane, diethyldimethoxysilane, diethyldiethoxysilane, diethyldipropoxysilane, diethyldiphenoxysilane, dipropyldimethoxysilane, dipropyldiethoxysilane, diphenyldimethoxysilane, diphenyldiethoxysilane, diphenyldiphenoxysilane, bis(3,3,3-trifluoropropyl)dimethoxysilane, methyl(3,3,3-trifluoropropyl)dimethoxysilane, methyltrimethoxysilane, methylphenyldimethoxysilane, ethyltrimethoxysilane, propyltrimethoxysilane, isopropyltrimethoxysilane, phenyltrimethoxysilane, methyltriethoxysilane, methylphenyldiethoxysilane, ethyltriethoxysilane, propyltriethoxysilane, isopropyltriethoxysilane, phenyltriethoxysilane, methyltripropoxysilane, ethyltripropoxysilane, propyltripropoxysilane, isopropyltripropoxysilane, phenyltripropoxysilane, methyltriisopropoxysilane, ethyltriisopropoxysilane, propyltriisopropoxysilane, isopropyltriisopropoxysilane, phenyltriisopropoxysilane, trifluoromethyltrimethoxysilane, pentafluoroethyltrimethoxysilane, 3,3,3-trifluoropropyltrimethoxysilane, and 3,3,3-trifluoropropyltriethoxysilane.

Among the above examples, in terms of heat resistance and transparency in a case where the polysiloxane compound is formed into a cured film, preferred examples thereof include phenyltrimethoxysilane, phenyltriethoxysilane, methylphenyldimethoxysilane, and methylphenyldiethoxysilane. Further, in terms of increasing the flexibility and preventing the cracking and the like in a case where the polysiloxane compound is formed into a cured film, preferred examples thereof include dimethyldimethoxysilane and dimethyldiethoxysilane.

In a case where the silicon compound (Z) is used, only one kind thereof may be used, or two or more kinds thereof may be used.

In a case where the silicon compound (Z) is used, the amount thereof may be appropriately adjusted according to the desired performance and the like. Specifically, in a case where the silicon compound (Z) is used, the amount thereof is, for example, 1% to 50% by mole and preferably 5% to 40% by mole in all the polymerizable components (the silicon compounds (X), (Y), and (Z)) which are used in polycondensation).

In addition, in a case where a silicon compound (Z1) is used, the amount thereof is preferably 1% to 50% by mole and more preferably 5% to 40% by mole in all the polymerizable components which are used in polycondensation, in consideration of the balance between curability and other performance.

It is noted that, in general, the preparation ratio between the silicon compounds (X), (Y), and (Z) can be regarded to be roughly the same as the ratio between structural units respectively corresponding to the silicon compounds (X), (Y), and (Z) in the polysiloxane compound.

<Resin Composition, Cured Film of Resin Composition, and Production Method of Cured Film>

The resin composition of the present embodiment contains the above-described polysiloxane compound and a solvent. In other words, the resin composition of the present embodiment is a resin composition obtained by dissolving and/or dispersing the above-described polysiloxane compound in a solvent. It is possible to form a resin film by dissolving and/or dispersing the polysiloxane compound in a solvent to obtain a resin composition, applying the resin composition onto a base material, and then drying the solvent. Further, it is possible to manufacture a cured film by heating the resin film.

The solvent typically includes an organic solvent. Examples of the solvent that can be preferably used include propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutylacetate, 2-heptanone, N,N-dimethylformamide, N,N-dimethylacetamide, and N-methylpyrrolidone.

Further, examples of the solvent that can be used also include glycols, glycol ethers, and glycol ether esters. Specific examples thereof include CELTOL (registered trade name) manufactured by Daicel Corporation and Highsolve (registered trade name) manufactured by TOHO Chemical Industry Co., Ltd. More specific examples thereof include cyclohexanol acetate, dipropylene glycol dimethyl ether, propylene glycol diacetate, dipropylene glycol methyl-n-propylether, dipropylene glycol methyl ether acetate, 1,4-butanediol diacetate, 1,3-butylene glycol diacetate, 1,6-hexanediol diacetate, 3-methoxybutyl acetate, ethylene glycol monobutyl ether acetate, diethylene glycol monoethyl ether acetate, diethylene glycol monobutyl ether acetate, triacetin, 1,3-butylene glycol, propylene glycol-n-propyl ether, propylene glycol-n-butyl ether, dipropylene glycol methyl ether, dipropylene glycol ethyl ether, dipropylene glycol-n-propyl ether, dipropylene glycol-n-butyl ether, tripropylene glycol methyl ether, tripropylene glycol-n-butyl ether, triethylene glycol dimethyl ether, diethylene glycol butyl methyl ether, tripropylene glycol dimethyl ether, and triethylene glycol dimethyl ether.

The solvent may be a single solvent or a mixed solvent.

The using amount of the solvent is not particularly limited; however, the total solid content (the components other than the volatile solvent) in the resin composition is usually 5% to 60% by mass and preferably 10% to 50% by mass. In a case where the total solid content concentration is suitably adjusted, the ease of forming a thin film or the uniformity of the film thickness tends to be improved.

The resin composition of the present embodiment may contain one or more additive components in addition to the polysiloxane compound and the solvent.

For example, an additive such as a surfactant can be added for the purpose of improving coatability, levelability, film forming property, storage stability, or defoaming property. Specific examples thereof include commercially available surfactants such as trade name MEGAFACE, product number F142D, F172, F173, or F183, manufactured by DIC Corporation; trade name Florard, product number, FC-135, FC-170C, FC-430, or FC-431, manufactured by Sumitomo 3M Limited; trade name Surflon, product number S-112, S-113, S-131, S-141, or S-145, manufactured by AGC SEIMI CHEMICAL Co., Ltd.; and trade name SH-28PA, SH-190, SH-193, SZ-6032, or SF-8428, manufactured by Dow Toray Co., Ltd.

(“MEGAFACE,” “Florard,” and “Surflon” are registered trade names of the respective companies.)

In a case where a surfactant is used, only one surfactant may be used, or two or more surfactants may be used.

In a case where a surfactant is used, the amount thereof is usually 0.001 to 10 parts by mass with respect to 100 parts by mass of the polysiloxane compound.

As another additive component, a curing agent can be blended for the intended purpose of improving the chemical liquid resistance of the cured film to be formed. Examples of the curing agent include a melamine curing agent, a urea resin curing agent, a polybasic acid curing agent, an isocyanate curing agent, and an epoxy curing agent.

Specific examples thereof include isocyanates such as isophorone diisocyanate, hexamethylene diisocyanate, tolylene diisocyanate, and diphenylmethane diisocyanate, and isocyanurates, blocked isocyanates, or biurets of the isocyanates; amino compounds such as melamine resins such as an alkylated melamine, methylol melamine, and imino melamine or urea resins; and an epoxy curing agent having two or more epoxy groups, which is obtained by the reaction of a multivalent phenol such as bisphenol A with epichlorohydrin.

In a case where a curing agent is used, only one curing agent may be used, or two or more curing agents may be used.

In a case where a curing agent is used, the amount thereof is usually 0.001 to 10 parts by mass with respect to 100 parts by mass of the polysiloxane compound.

The method of manufacturing a cured film using the resin composition of the present embodiment can include, for example;

a film forming step of applying the resin composition of the present embodiment onto a base material to form a resin film, and

a curing step of heating the resin film to make the resin film into a cured film. Hereinafter, the film forming step and the curing step will be specifically described.

Film Forming Step

In the film forming step, the base material onto which the resin composition is applied is not particularly limited. A silicon wafer or a base material made of metal, glass, ceramic, or plastic is selected depending on the intended use of the cured film to be formed.

The coating method and the coating device in the film formation are not particularly limited. A known coating method/device such as spin coating, dip coating, spray coating, bar coating, an applicator, ink jet, or roll coater can be applied.

In a case where the base material coated with the resin composition is heated at, for example, 80° C. to 120° C. for 30 seconds to 5 minutes, the solvent in the resin composition can be volatilized to obtain a resin film.

Curing Step

In a case where the resin film formed in the film forming step is further subjected to heat treatment, a cured film can be obtained. The temperature of the heat treatment is usually 100° C. to 350° C. Although being dependent on the boiling point of the solvent, a more preferred temperature is 150° C. to 280° C. In a case where heating is carried out at a properly high temperature, the processing speed can be increased. On the other hand, in a case where the heating temperature is not too high, the uniformity of the cured film can be improved.

<Photosensitive Resin Composition, Patterned Cured Film, and Method of Manufacturing Patterned Cured Film>

The photosensitive resin composition of the present embodiment contains the above-described polysiloxane compound, a photoacid generator, and a solvent. In other words, a photoacid generator is further added to the above-described resin composition, whereby the photosensitive resin composition of the present embodiment can be produced.

The photoacid generator is not particularly limited as long as it is a compound that generates an acid upon irradiation with light such as ultraviolet rays.

In a case where the acid generated upon irradiation with light acts on the acid unstable group in the polysiloxane compound, the acid unstable group is eliminated to generate the HFIP group. This makes the polysiloxane compound soluble in an alkaline developing liquid. On the other hand, in a case of the absence of light irradiation, the polysiloxane compound remains insoluble in an alkaline developing liquid. By utilizing such a change in solubility in an alkaline developing liquid upon irradiation with light, it is possible to manufacture a patterned resin film from a photosensitive resin composition. Further, a patterned cured film can be obtained by curing the pattern thereof.

Specific examples of the photoacid generator include a sulfonium salt, an iodonium salt, sulfonyl diazomethane, N-sulfonyloxyimide, and oxime-O-sulfonate. The photoacid generator is not particularly limited as long as it generates an acid capable of eliminating an acid unstable group. The photoacid generator may be used alone, or two or more kinds thereof may be used in combination.

Specific examples of the commercially available product of the photoacid generator include trade names Irgacure PAG121, Irgacure PAG103, Irgacure CGI1380, and Irgacure CGI725 (all manufactured by BASF SE); trade names: PAI-101, PAI-106, NAI-105, NAI-106, TAZ-110, and TAZ-204 (all manufactured by Midori Kagaku Co., Ltd.); trade names CPI-200K, CPI-210S, CPI-101A, CPI-110A, CPI-100P, CPI-110P, CPI-100TF, CPI-110TF, HS-1, HS-1A, HS-1P, HS-1N, HS-1TF, HS-1NF, HS-1MS, HS-1CS, LW-Si, and LW-S1NF (all manufactured by San-Apro Ltd.); and trade names TFE-triazine, TME-triazine, and MP-triazine (all manufactured by Sanwa Chemical Co., Ltd.). Needless to say, the photoacid generator that can be used is not limited to these.

In a case where a photoacid generator is used, only one photoacid generator may be used, or two or more photoacid generators may be used.

The amount of the photoacid generator is, for example, 0.01 to 10 parts by mass and preferably 0.05 to 5 parts by mass, in a case where the polysiloxane compound is set to 100 parts by mass. In a case where a proper amount of the photoacid generator is used, it is possible to achieve both sufficient sensitivity or resolution and storage stability of the composition.

The photosensitive resin composition of the present embodiment may contain one or more additive components as in the case of the above-described resin composition. Examples of the additive component that can be added are also as described above.

In terms of “photosensitivity”, a sensitizing agent may be used as the additive component. The sensitizing agent preferably has light absorption for an exposure wavelength (for example, 365 nm (I line), 405 nm (h line), and 436 nm (g line)) in the exposure treatment. However, in a case where the sensitizing agent remains on the cured film as it is, the problem of reduced transparency may occur. For this reason, the sensitizing agent is preferably a compound that is vaporized by heat treatment such as thermosetting or a compound that is discolored upon irradiation with light, such as bleaching exposure.

Specific examples of the sensitizing agent include coumarin such as 3,3′-carbonylbis(diethylaminocoumarin); anthracene such as 9,10-anthracene; aromatic ketones such as benzophenone, 4,4′-dimethoxybenzophenone, acetophenone, 4-methoxyacetophenone, and benzaldehyde; and condensed aromatic compound such as biphenyl, 1,4-dimethylnaphthalene, 9-fluorenone, fluorene, phenanthrene, triphenylene, pyrene, anthracene, 9-phenylanthracene, 9-methoxyanthracene, 9,10-diphenylanthracene, 9,10-bis(4-methoxyphenyl)anthracene, 9,10-bis(triphenylsilyl)anthracene, 9,10-dimethoxyanthracene, 9,10-diethoxyanthracene, 9,10-dipropoxyanthracene, 9,10-dibutoxyanthracene, 9,10-dipentaoxyanthracene, 2-t-butyl-9,10-dibutoxyanthracene, and 9,10-bis(trimethylsilylethynyl)anthracene. Examples of the commercially available product include ANTHRACURE (manufactured by Kawasaki Kasei Chemicals Ltd.).

In a case where a sensitizing agent is used, only one kind thereof may be used, or two or more kinds thereof may be used.

In a case where a sensitizing agent is used, the blending amount thereof is usually 0.001 to 10 parts by mass with respect to 100 parts by mass of the polysiloxane compound.

In addition, examples of the additive component also include an organic basic compound (an amine compound or a nitrogen-containing heterocyclic compound) that is commonly used in photosensitive resin composition containing an acid unstable group.

In the photosensitive resin composition of the present embodiment, the using amount of the solvent can be the same as that of the above-described resin composition.

A patterned cured film can be produced by using the photosensitive resin composition of the present embodiment. The patterned cured film can be manufactured through a series of steps including, for example;

a film forming step of applying a photosensitive resin composition onto a base material to form a photosensitive resin film,

an exposure step of exposing the photosensitive resin film,

a developing step of developing the exposed photosensitive resin film to form a patterned resin film, and

a curing step of heating the patterned resin film to make the patterned resin film into a patterned cured film.

Hereinafter, a description will be added in each of the above steps.

Film Forming Step

As the base material that is coated with the photosensitive resin composition, for example, a silicon wafer or a base material made of metal, glass, ceramic, or plastic is selected depending on the intended use of the cured film to be formed.

As the coating method, a conventionally known coating method such as spin coating, dip coating, spray coating, bar coating, or a method using an applicator, ink jet, or roll coater can be applied without particular limitation.

The base material coated with the photosensitive resin composition is heated at, for example, 80° C. to 120° C. for about 30 seconds to 5 minutes to dry the solvent. This makes it possible to obtain a photosensitive resin film.

Exposure Step

For example, the photosensitive resin film obtained in the film forming step is irradiated with light through a photomask for forming a target pattern.

A known method or device can be used for the exposure treatment. As the light source, a light source having a wavelength in the range of 100 to 600 nm can be used. Specifically, a low-pressure mercury lamp, a high-pressure mercury lamp, an ultra-high-pressure mercury lamp, a KrF excimer laser (wavelength: 248 nm), an ArF excimer laser (wavelength: 193 nm), or the like can be used. The exposure amount is usually about 1 to 10,000 mJ/cm² and preferably about 10 to 5,000 mJ/cm².

After the exposure, post-exposure heating can be carried out before the developing step as necessary. The temperature of post-exposure heating is preferably 60° C. to 180° C., and the time of post-exposure heating is preferably 0.5 to 10 minutes.

Developing Step

Next, the exposed photosensitive resin film obtained in the exposure step is subjected to developing, whereby a film having a pattern shape (hereinafter, also described as a “patterned resin film”) is produced. An alkaline aqueous solution is used as a developing liquid to dissolve exposed portions in the exposed photosensitive resin film, whereby a patterned resin film is formed.

The developing liquid is not particularly limited as long as it can remove the photosensitive resin film in the exposed portions. Specific examples thereof include an inorganic alkali, a primary amine, a secondary amine, a tertiary amine, an alcohol amine, a quaternary ammonium salt, and an alkaline aqueous solution in which a mixture of this compound is dissolved.

More specific examples thereof include an alkaline aqueous solution of a compound such as potassium hydroxide, sodium hydroxide, ammonia, ethylamine, diethylamine, triethylamine, triethanolamine, or tetramethylammonium hydroxide (abbreviation: TMAH). Among the above, it is preferable to use a TMAH aqueous solution, and in particular, it is preferable to use a TMAH aqueous solution of 0.1% by mass or more and 5% by mass or less and more preferably 2% by mass or more and 3% by mass or less.

As the developing method, a known method such as an immersion method, a puddle method, or a spraying method can be used. The development time is usually 0.1 to 3 minutes and preferably 0.5 to 2 minutes. Then, as necessary, washing, rinsing, drying and the like can be carried out to form a target patterned film (a patterned resin film) on the base material.

Curing Step

The patterned resin film obtained in the developing step is subjected to heat treatment to obtain a final patterned cured film. With heat treatment, it is possible to condense the alkoxy group or the silanol group, which remains as an unreactive group in the polysiloxane compound. Further, in a case where the photosensitive resin composition contains an epoxy group, an oxetane group, a methacryloyl group, an acryloyl group, and the like, these groups can be sufficiently cured.

The heating temperature is preferably 80° C. to 400° C. and more preferably 100° C. to 350° C. The heating time is usually 1 to 90 minutes and preferably 5 to 60 minutes. In a case where the heating temperature and the heating time are suitably adjusted, the resin film can be sufficiently cured while the decomposition of the components contained in the resin film is suppressed. In addition, it is easy to obtain a cured film having good chemical resistance, high transparency, and suppressed cracking occurrence.

### Reference Embodiment

In the above section of <Silicon compound and reactive material>, it has been described that the reactive material of the present embodiment can further contain a silicon compound (Y) represented by General Formula (y).

Regarding the above, a part of the embodiments of the present invention can also be regarded as the following “composition”.

“A composition containing a silicon compound (X) represented by General Formula (x) and a silicon compound (Y) represented by General Formula (y),

in which in a case where the mass of the silicon compound (X) contained in the composition is denoted by M_{X} and the mass of the silicon compound (Y) is denoted by M_{Y}, the ratio (% by mass) of the silicon compound (Y), represented by {M_{Y}/(M_{X}+M_{Y})}×100 is preferably 1×10⁻⁴% to 12%, more preferably 5×10⁻⁴% to 10%, still more preferably 0.001% to 8%, and particularly preferably 0.01% to 5%”

In this composition, the definitions and preferred aspects of the silicon compound (X) represented by General Formula (x) and the silicon compound (Y) represented by General Formula (y) are as described above. This composition may contain or may not contain an optional component other than the silicon compound (X) and the silicon compound (Y). Examples of the optional component include a solvent (an organic solvent or the like) and a stabilizing agent, as well as water or an impurity, which is unavoidably contained.

The embodiments of the present invention have been described above; however, these are examples of the present invention, and thus it is possible to adopt various configurations other than the above. In addition, the present invention is not limited to the embodiments described above and modifications, improvements, and the like are included in the present invention in a range in which it is possible to achieve the purpose of the present invention.

### EXAMPLE

The embodiments of the present invention will be described in more detail based on Examples and Comparative Examples. It is noted, just to be sure, that the present invention is not limited to only Examples.

Unless otherwise specified, some compounds are described as follows in Examples.
THF: Tetrahydrofuran
MOMCl: Chloromethyl methyl ether
Boc₂O: Di-tert-butyl ecarbonate
TBAI: Tetrabutylammonium iodide
TMAH: Tetramethylammonium hydroxide
Ph-Si: Phenyltriethoxysilane
KBM-303: 2-(3,4-epoxycyclohexyl)ethyltrimethoxysilane, manufactured by Shin-Etsu Chemical Co., Ltd.
KBM-5103: 3-acryloxypropyltrimethoxysilane, manufactured by Shin-Etsu Chemical Co., Ltd.
Ethyl polysilicate: Silicate 40, manufactured by Tama Chemicals Co., Ltd.
HFA-Si: A compound represented by the following chemical formula

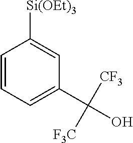

HFA-Si-MOM: A compound represented by the following chemical formula

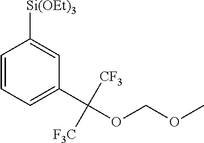

HFA-Si-BOC: A compound represented by the following chemical formula

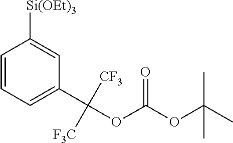

The device used for various measurements and the measurement conditions will be described in advance.

(Nuclear magnetic resonance (NMR))

¹H-NMR and ¹⁹F-NMR were measured using a nuclear magnetic resonance apparatus (device name: JNM-ECA-400, manufactured by JEOL Ltd.) having a resonance frequency of 400 MHz.

(Gas Chromatography (GC))

A gas chromatograph (device name: Shimadzu GC-2010), manufactured by Shimadzu Corporation, was used, and a capillary column (type: DB5 (length: 30 mm×inner diameter: 0.25 mm×film thickness: 0.25 μm), manufactured by Agilent Technologies, Inc., was used.

(Gel Permeation Chromatography (GPC))

A high-speed GPC device (device name: HLC-8320GPC), manufactured by Tosoh Corporation, was used to measure the weight average molecular weight in terms of polystyrene.

### Production of Reactive Material

### Synthesis Example 1-1: Production of Reactive Material Containing HFA-Si-MOM

HFA-Si (150 g, 0.37 mol) was dropwise added to a solution of a mixture of THF (150 g) and NaH (16.2 g, 0.41 mol) in a three-necked flask placed in an ice bath, and then MOMCl (32.6 g, 0.38 mol) was dropwise added thereto. Then, the mixture was stirred at room temperature for 20 hours.

After the above stirring was completed, the reaction solution was concentrated with an evaporator. 300 g of toluene and 150 g of water were charged to the concentrated reaction solution and stirred. After stirring, the mixture was allowed to stand for a while to separate the mixture into two layers, and then the lower aqueous layer was removed. 150 g of water was further charged to the obtained upper organic layer, and the same operation above was repeated. The finally obtained upper organic layer was concentrated with an evaporator to obtain 180 g of a crude product.

The obtained crude product was subjected to simple distillation (vacuum degree: 2.5 kPa, bath temperature: 200° C. to 220° C., top temperature: 170° C.) to obtain 145 g of a reactive material (liquid) containing HFA-Si-MOM.

In the above, the yield of HFA-Si-MOM was 84.3%, and the GC purity was 97%. In addition, the obtained reactive material contained a small amount of HFA-Si, and the ratio of HFA-Si was 0.1% by mass, where the ratio of HFA-Si was calculated by {amount of HFA-Si/(amount of HFA-Si-MOM+amount of HFA-Si)}×100.

The signals obtained by NMR measurement are shown below.

¹H-NMR (solvent: CDCl₃, TMS): δ7.92 (s, 1H), 7.79-7.76 (m, 1H), 7.68-7.67 (m, 1H), 7.49-7.45 (m, 1H), 4.83 (s, 2H), 3.86 (q, 6H), 3.55 (s, 3H), 1.23 (t, 9H)

¹⁹F-NMR (solvent: CDCl₃, C₆F₆): δ−71.4 (s, 6F)

### Synthesis Example 1-2: Production of HFA-Si-BOC

THF (10 g), NaH (1.2 g, 0.03 mol), and HFA-Si (10 g, 0.025 mol) were added in a three-necked flask placed in an ice bath and stirred for 30 minutes. Then, Boc₂O (5.2 g, 0.027 mol) and TBAI (0.3 g, 0.001 mol) were added to the flask, and the resultant mixture was stirred at room temperature for 18 hours.

Diisopropyl ether (20 g) and water (10 g) were added to the obtained reaction product, stirred, and then allowed to stand for a while. After allowing the mixture to stand and to be separated into two layers, the lower aqueous layer was removed. The obtained upper organic layer was dried with magnesium sulfate and then concentrated with an evaporator to obtain 10 g of HFA-Si-BOC (yield: 83%, GC purity: 95%).

The signals obtained by NMR measurement are shown below.

¹H-NMR (solvent: CDCl₃, TMS): δ7.78-7.75 (m, 2H), 7.52-7.43 (m, 2H), 3.84 (q, 6H), 1.46 (s, 9H), 1.22 (t, 9H)

¹⁹F-NMR (solvent: CDCl₃, C₆F₆): δ−70.2 (s, 6F)

<Preparation of Comparative Compound>

HFA-Si was synthesized according to the procedure described in paragraph 0124 in Example 5 of International Publication No. 2019/167770.

<Evaluation of Storage Stability>

As a sample for evaluation, the reactive material (containing 0.1% by mass of HFA-Si corresponding to the silicon compound (Y)) produced in Synthesis Example 1-1 was prepared (this sample is referred to as a “sample 1”). In addition, samples 2 to 5 were prepared by further adding HFA-Si to the reactive material of the sample 1.

The ratio of the silicon compound (Y) represented by {M_{Y}/(Mₓ+M_{y})}×100 in each sample is shown in the table below.

parts by mass of water, in a case where the total amount of HFA-Si-MOM and HFA-Si was set to 100 parts by mass, was added in each sample, and the sample was stored in a refrigerator for 24 hours. Before and after storage, GPC measurement and GC measurement were carried out to evaluate storage stability.

Table 2 below shows the evaluation results obtained based on the following evaluation criteria.
GPC measurement: regarding the value of weight average molecular weight Mw after refrigeration storage for 24 hours with respect to Mw at the start of storage,

without a change: the amount of change in Mw value is within ±20,

with a change: the amount of increase in Mw value is 200 or more.
GC measurement: regarding the GC purity after refrigeration storage for 24 hours with respect to the GC purity at the start of storage,

without a change: the amount of change in GC purity is within ±1.5%,

with a change: the amount of decrease in GC purity is 10% or more.

(“GC purity” represents the purity of HFA-Si-MOM in the sample, where the purity is obtained from the area in the chart obtained by the gas chromatograph measurement.)

The evaluation results of each sample are shown below.

TABLE 2

| | Ratio of silicon | | |
|---|---|---|---|
| | compound (Y) | GPC | GC |
| | {M_{Y}/(M_{X} + M_{Y})} × 100 | measurement | measurement |
| Sample No. | (% by mass) | result | result |
| Sample 1 | 0.1 | Without change | Without change |
| Sample 2 | 5 | Without change | Without change |
| Sample 3 | 10 | Without change | Without change |
| Sample 4 | 15 | With change | With change |
| Sample 5 | 20 | With change | With change |

From Table 2, it was shown that the storage stability of the reactive material having a small ratio of the silicon compound (Y), represented by {M_{Y}/(Mₓ+M_{y})}×100, is particularly good.

### Production of Polysiloxane Compound

### Synthesis Example 2-1: Synthesis of Polysiloxane Compound Under Basic Conditions

The reactive material (1.0 g, 2.2 mmol) containing HFA-Si-MOM, obtained in Synthesis Example 1-1, EtOH (0.5 g), water (0.13 g, 7.0 mmol), and a 25% by mass TMAH aqueous solution (0.002 g, 0.02 mmol in terms of TMAH) were placed in a reaction container, and the reaction was carried out at 60° C. for 4 hours with stirring.

Then, toluene (5 g) was added to the reaction solution, and the mixture was refluxed at 105° C. for 20 hours with a Dean-Stark apparatus to distill off water and EtOH. Further, washing with water was carried out 3 times (2 g of water was used for each washing), and the organic layer was concentrated with an evaporator (conditions: 30 hPa, 60° C., and 30 min).

From the above, 0.8 g of a target polysiloxane compound was obtained. The weight average molecular weight Mw measured by GPC was 2,100.

### Comparative Synthesis Example 2-1: Synthesis of Polysiloxane Compound Under Base Conditions

HFA-Si (1 g, 2.5 mmol), EtOH (1 g), water (0.14 g, 7.8 mmol), and a 25% by mass TMAH aqueous solution (0.002 g, 0.02 mmol in terms of TMAH) were placed in a reaction container, and the reaction was carried out at 60° C. for 4 hours with stirring.

Then, toluene (5 g) was added to the reaction solution, and the mixture was refluxed at 105° C. for 20 hours with a Dean-Stark apparatus to distill off water and EtOH. Further, washing with water was carried out 3 times (2 g of water was used for each washing), and the organic layer was concentrated with an evaporator (conditions: 30 hPa, 60° C., and 30 min).

As a result, 0.8 g of a polysiloxane compound was obtained. The weight average molecular weight Mw measured by GPC was 1,000.

### Comparative Synthesis Example 2-2: Synthesis of Polysiloxane Compound Under Base Conditions

HFA-Si (1 g, 2.5 mmol), NaOH (0.4 g, 3.0 mmol), water (0.14 g, 7.8 mmol), and EtOH (1 g) were placed in a reaction container, and the reaction was carried out at 60° C. for 4 hours with stirring. As a result of the reaction, a polysiloxane compound was obtained. The weight average molecular weight Mw measured by GPC was 1,300.

In Synthesis Example 2-1, a polysiloxane compound having a relatively large Mw was obtained. However, the Mw of the polysiloxane compound obtained in Comparative Synthesis Example 2-1 and Comparative Synthesis Example 2-2 was much smaller than the Mw in Synthesis Example 2-1. From this, it can be said that the reactivity of the reactive material of the present embodiment is good, at least from the viewpoint of polymerizability.

In addition, it was shown that the reactive material of the present embodiment has good storage stability and good reactivity in addition to the above-described evaluation results of the storage stability of the reactive material (the storage stability is good).

### Synthesis Example 2-2: Synthesis of Polysiloxane Compound Under Acidic Conditions

The reactive material (1.0 g, 2.2 mmol) containing HFA-Si-MOM, obtained in Synthesis Example 1-1, acetone (2 g), water (4.13 g, 7.0 mmol), and acetic acid (0.02 g, 0.1 mmol) were added to a reaction container, and the reaction was carried out at 60° C. for 20 hours. Then, using an evaporator, acetone and water were distilled off from the reaction solution to obtain 0.8 g of a polymer (yield: 100%). The weight average molecular weight Mw measured by GPC was 1,600. Moreover, according to the analysis by ¹⁹F-NMR, the methoxymethyl group was not eliminated.

From the above, it was shown that the reactive material of the present embodiment can be preferably used as a raw material of the polysiloxane compound even under acidic conditions.

### Synthesis Example 2-1′ and Synthesis Example 2-3 to 2-9: Synthesis of Polysiloxane Compound and Preparation of Solution Composition

A polysiloxane compound was obtained in the same manner except that in Synthesis Example 2-1, KOH was used as the polymerization catalyst instead of TMAH (Synthesis Example 2-1′).

In addition, a polysiloxane compound was obtained in the same manner except that in Synthesis Example 2-2, hydrochloric acid was used as the polymerization catalyst instead of acetic acid (Synthesis

Example 2-3). Further, a polysiloxane compound was obtained in the same manner except that in Synthesis Example 2-1, the kind of raw material and the preparation ratio were changed as shown in the table below (Synthesis Examples 2-4 to 2-9).

Then, the polysiloxane compounds obtained in Synthesis Examples 2-1, 2-1′, and 2-2 to 2-9 were dissolved in propylene glycol monomethyl ether acetate (PGMEA) to respectively obtain solution compositions (resin compositions) P-1, P-1′, and P-2 to P-9, having a concentration of 25% by mass.

The matters related to the above are summarized in the table below. In the table below, “HFA-Si-MOM” represents the reactive material containing HFA-Si-MOM, obtained in Synthesis Example 1-1.

TABLE 3

| Synthesis | | | | |
|---|---|---|---|---|
| Example | Solution | Preparation composition ratio | Polymerization | Mw of |
| number | composition | (molar ratio) | catalyst | polysiloxane |
| 2-1 | P-1 | HFA-Si-MOM | TMAH | 2100 |
| 2-1′ | P-1′ | HFA-Si-MOM | KOH | 2600 |
| 2-2 | P-2 | HFA-Si-MOM | Acetic acid | 1600 |
| 2-3 | P-3 | HFA-Si-MOM | Hydrochloric | 1700 |
| | | | acid | |
| 2-4 | P-4 | HFA-Si-Boc | TMAH | 1800 |
| 2-5 | P-5 | HFA-Si-MOM/Ph—Si/KBM-303 (1/8/1) | TMAH | 1700 |
| 2-6 | P-6 | HFA-Si-MOM/Ph—Si/KBM-303 (3/5/2) | TMAH | 2000 |
| 2-7 | P-7 | HFA-Si-MOM/Ph—Si/KBM-303 (5/2/3) | TMAH | 1900 |
| 2-8 | P-8 | HFA-Si-MOM/Ph—Si/KBM-5103 (1/1/1) | TMAH | 1800 |
| 2-9 | P-9 | HFA-Si-MOM/Ethyl polysilicate (8/2) | TMAH | 1700 |

<Formation of Film of Solution Composition and Evaluation of Tackiness>

Each of the solution compositions P-1, P-1′, and P-2 to P-9 was spin-coated onto a silicon wafer, manufactured by SUMCO Corporation, having a diameter of 4 inches and a thickness of 525 μm, at a rotation speed of 500 rpm. Then, the coated silicon wafer was dried on a hot plate at 100° C. for 3 minutes. Then, baking was carried out at 230° C. for 1 hour. In this manner, a cured film of polysiloxane having a film thickness of 1 to 2 μm was obtained.

When the presence or absence of tackiness was checked by finger touching, tackiness was not observed in any of the films. That is, it was confirmed that the polysiloxane compound obtained by polycondensing the reactive material of the present embodiment in the presence of an acidic catalyst or a basic catalyst has no significant problem in application to film formation and the like.

[Transparency Evaluation]

A cured film of polysiloxane having a film thickness of 1 to 2 μm was obtained in the same manner as above, except that each of the solution compositions P-1, P-1′, and P-2 to P-9 was used and a 4-inch glass substrate was used instead of the 4-inch silicon wafer. Then, the transmission spectrum of the cured film was measured.

All the transmittances of the cured films obtained from the solution compositions P-1, P-1′, P-2 to P-9 at a wavelength of 400 nm in terms of a film thickness of 2 μm were more than 90%. All the transmittances of the cured films obtained from the P-1, P-1′, P-2 to P-4, and P-9 at a wavelength of 350 nm in terms of a film thickness of 2 μm were more than 90%.

Due to such good light transmittance at a wavelength of 350 to 400 nm, the polysiloxane compound obtained by polycondensing the reactive material of the present embodiment in the presence of an acidic catalyst or a basic catalyst is preferably applicable to, for example, a photosensitive resin composition that is applied to the i line exposure, an organic EL, a liquid crystal display, and a coating material for a CMOS image sensor.

<Preparation of Photosensitive Resin Composition and Evaluation of Patterning Properties>

0.04 g of a photoacid generator CPI-100TF (manufactured by San-Apro Ltd.) was added to 3 g of each of the solution compositions P-1, P-1′, and P-2 to P-4 and stirred to produce each of uniform photosensitive resin compositions (five kinds).

A silicon wafer having a diameter of 4 inches and a thickness of 525 μm, manufactured by SUMCO Corporation, was spin-coated with each of the obtained photosensitive resin compositions at a rotation speed of 500 rpm. Then, the coated silicon wafer was heat-treated on a hot plate at 100° C. for 3 minutes to obtain a photosensitive resin film having a film thickness of 1 to 2 μm.

Using an exposure apparatus having a high-pressure mercury lamp, the photosensitive resin film was irradiated with light of 108 mJ/cm² through a photomask. Then, the irradiated photosensitive resin film was heat-treated on a hot plate at 150° C. for 1 minute. After the heat treatment, immersion in a 2.38% by mass TMAH aqueous solution was carried out for 1 minute for development, and then immersion in water was carried out for 30 seconds for washing. After washing, the photosensitive resin film was baked in an oven at 230° C. for 1 hour in the air.

As a result, a patterned cured film in which a positive pattern was formed was obtained. A line and space pattern of 10 to 20 μm could be resolved in all five photosensitive resin compositions. That is, it can be said that the polysiloxane compound obtained by polycondensing the present reactive material is preferably applicable to the photosensitive resin composition.

### INDUSTRIAL APPLICABILITY

The silicon compound and the reactive material of the present embodiment are useful as a raw material for synthesizing a polymer, a modifier for a polymer, a surface treatment agent for an inorganic compound, a coupling agent for various materials, an intermediate raw material for organic synthesis, and the like.

Further, in a case where a photosensitizer is added to a resin composition containing the polysiloxane compound obtained by polycondensing the silicon compound or the reactive material of the present embodiment, the resin composition can be made into a photosensitive resin composition with which patterning by alkaline development is possible.

Further, the cured film obtained from the resin composition or the photosensitive resin composition of the present embodiment has excellent transparency. From this, the resin composition or the photosensitive resin composition of the present embodiment is suitably used for a protective film for a semiconductor, a protective film for organic EL or a liquid crystal display, a coating material for an image sensor, a flattening material, a microlens material, an insulating protective film material for a touch panel, a flattening material for a liquid crystal display TFT, a core or clad forming material for an optical waveguide, a resist for an electron beam, an intermediate film for a multilayer resist, an underlayer film, an antireflection film, and the like. Among these use applications described above, in a case of being used for optical system members such as a display and an image sensor, fine particles such as polytetrafluoroethylene, silica, titanium oxide, zirconium oxide, and magnesium fluoride are mixed and used in any ratio for the purpose of adjusting the refractive index.

This application claims priority based on Japanese Patent Application No. 2019-195382 filed on Oct. 28, 2019, and all contents of the disclosure are incorporated herein.

1. A silicon compound represented by General Formula (x), 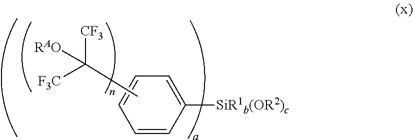
in General Formula (x),
in a case where a plurality of R¹'s are present, R¹'s are each independently a linear alkyl group having 1 to 10 carbon atoms, a branched alkyl group having 3 to 10 carbon atoms, a cyclic alkyl group having 3 to 10 carbon atoms, a linear alkenyl group having 2 to 10 carbon atoms, a branched alkenyl group having 3 to 10 carbon atoms, or a cyclic alkenyl group having 3 to 10 carbon atoms, where all or part of hydrogen atoms in the alkyl group or the alkenyl group may be substituted with a fluorine atom,
in a case where a plurality of R²'s are present, R²'s are each independently a linear alkyl group having 1 to 4 carbon atoms or a branched alkyl group having 3 or 4 carbon atoms, where all or part of hydrogen atoms in the alkyl group may be substituted with a fluorine atom,
R^{A} is an acid unstable group,
a is an integer of 1 to 3, b is an integer of 0 to 2, and c is an integer of 1 to 3, where a+b+c=4 is satisfied, and
n is an integer of 1 to 5.

2. The silicon compound according to claim 1,
wherein the R^{A} is at least any group selected from the group consisting of an alkyl group, an alkoxycarbonyl group, an acetal group, a silyl group, and an acyl group.

3. A reactive material comprising a silicon compound (X) represented by General Formula (x), 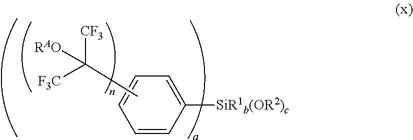
in General Formula (x),
in a case where a plurality of R¹'s are present, R¹'s are each independently a linear alkyl group having 1 to 10 carbon atoms, a branched alkyl group having 3 to 10 carbon atoms, a cyclic alkyl group having 3 to 10 carbon atoms, a linear alkenyl group having 2 to 10 carbon atoms, a branched alkenyl group having 3 to 10 carbon atoms, or a cyclic alkenyl group having 3 to 10 carbon atoms, where all or part of hydrogen atoms in the alkyl group or the alkenyl group may be substituted with a fluorine atom,
in a case where a plurality of R²'s are present, R²'s are each independently a linear alkyl group having 1 to 4 carbon atoms or a branched alkyl group having 3 or 4 carbon atoms, where all or part of hydrogen atoms in the alkyl group may be substituted with a fluorine atom,
R^{A} is an acid unstable group,
a is an integer of 1 to 3, b is an integer of 0 to 2, and c is an integer of 1 to 3, where a+b+c=4 is satisfied, and
n is an integer of 1 to 5.

4. The reactive material according to claim 3,
wherein the R^{A} is at least any group selected from the group consisting of an alkyl group, an alkoxycarbonyl group, an acetal group, a silyl group, and an acyl group.

5. The reactive material according to claim 3 or 4, further comprising:
a silicon compound (Y) represented by General Formula (y),
wherein in a case where a mass of the silicon compound (X) contained in the reactive material is denoted by M_{X} and a mass of the silicon compound (Y) contained in the reactive material is denoted by M_{Y}, a ratio of the silicon compound (Y), represented by {M_{Y}/(M_{X}+M_{y})}×100, is 1×10⁻⁴% to 12% by mass, 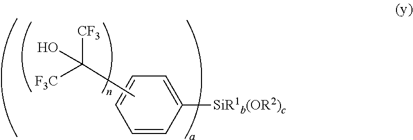
In General Formula (y), definitions of R¹, R², a, b, c, and n are respectively the same as those in General Formula (x).

6. A polysiloxane compound, wherein the polysiloxane compound is obtained by polycondensing the silicon compound according to claim 1 or 2 or the reactive material according to any one of claims 3 to 5 in a presence of an acidic catalyst or a basic catalyst.

7. The polysiloxane compound according to claim 6,
wherein a weight average molecular weight of the polysiloxane compound is 1,000 to 100,000.

8. A resin composition comprising:
the polysiloxane compound according to claim 6 or 7; and
a solvent.

9. The resin composition according to claim 8,
wherein the solvent includes at least one selected from the group consisting of propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols, glycol ethers, and glycol ether esters.

10. A photosensitive resin composition comprising:
the resin composition according to claim 8 or 9; and
a photoacid generator.

11. A cured film of the resin composition according to claim 8 or 9.

12. A method of manufacturing a cured film, comprising a heating step of applying the resin composition according to claim to 8 or 9 onto a base material and then carrying out heating at a temperature of 100° C. to 350° C.

13. A patterned cured film of the photosensitive resin composition according to claim 10.

14. A method of manufacturing a patterned cured film, comprising:
a film forming step of applying the photosensitive resin composition according to claim 10 onto a base material to form a photosensitive resin film;
an exposure step of exposing the photosensitive resin film;
a developing step of developing the exposed photosensitive resin film to form a patterned resin film; and
a curing step of heating the patterned resin film to make the patterned resin film into a patterned cured film.

15. The method of manufacturing a patterned cured film according to claim 14,
wherein a wavelength of light that is used for the exposure in the exposure step is 100 to 600 nm.
